(19) United States
(12) Patent Application Publication
(10) Pub. No.: US 2011/0073877 A1
(43) Pub. Date: Mar. 31, 2011

(54) HIGH-CURRENT/LOW COST READ-IN INTEGRATED CIRCUIT

(75) Inventor: Mark Alan Massie, Santa Ynez, CA (US)

(73) Assignee: NOVA RESEARCH, INC., Solvang, CA (US)

(21) Appl. No.: 12/892,156

(22) Filed: Sep. 28, 2010

Related U.S. Application Data
(60) Provisional application No. 61/246,230, filed on Sep. 28, 2009.

(51) Int. Cl. H01L 33/08; H01L 21/50

(52) U.S. Cl. 257/88; 438/34; 257/E21.499; 257/E33.066

(57) ABSTRACT

A Read-In Integrated Circuit scene generator incorporates an array of unit cells, with each cell having a switching control circuit. An array of emitting elements is associated with the unit cells and each element is connected with a lead to the switching control circuit of the associated cell. A first electrically conducting overlayer is deposited substantially covering the array of unit cells and connected for current supply. Each emitting element is connected to the first conducting overlayer and the first conducting overlayer includes vias through which each connecting lead from the emitting element to the switching control circuit extends. A second electrically conducting overlayer is deposited substantially covering the array of unit cells and connected for current return. Each switching control circuit is connected to the second conducting overlayer. The second conducting overlayer also has vias through which each lead from the emitting element extends to the switching circuit.

### REFERENCE TO RELATED APPLICATIONS

This application claims the priority of U.S. Provisional Application Ser. No. 61/246,230 filed on Sep. 28, 2010 having the same title as the present application.

### BACKGROUND INFORMATION

1. Field

Embodiments of the disclosure relate generally to the field of read-in integrated circuits (RIIC) for infrared emitters and more particularly to embodiments for a RIIC device that incorporates a “copper overlayer” process that serves the dual purpose of providing high supply and return current to the array of unit cells and also provides good thermal conduction to help keep the operating temperature of the circuitry cool.

2. Background

Infrared detection and imaging systems are being employed to sense temperature differences to create scenes displaying various objects. To accommodate testing of such systems, scene generators must be employed which provide high temperature emitters to accurately simulate inputs for test. In current devices a “suspended bridge” emitting device is attached to the RIIC. The large expense required to attach or otherwise deposit such suspended bridge technology contributes to the sales price of full infrared emitting systems to be over $1M. Also contributing to this price is the requirement that the technology incorporates patented subject matter requiring a license for the purpose of producing that patented emitting structure. Additionally, high temperature emitters typically require higher currents than can be provided by CMOS or other standard cell technologies employed in control and operation of RIIC based scene generators.

It is therefore desirable to provide RIIC unit cells which provide the capability to supply high currents required for high temperature emitters while using standard CMOS circuitry for control but at a reduced cost using simplified components. It is also desirable to provide a RIIC having high current output capability for enhanced emitter operation but provide thermal conduction for temperature control in the RIIC.

### SUMMARY

Exemplary embodiments provide a Read-In Integrated Circuit scene generator which incorporates an array of unit cells, with each cell having a switching control circuit. An array of emitting elements is associated with the unit cells and each element is connected with a lead to the switching control circuit of the associated cell. A first electrically conducting overlayer is deposited substantially covering the array of unit cells and connected for current supply. Each emitting element is connected to the first conducting overlayer and the first conducting overlayer includes vias through which each connecting lead from the emitting element to the switching control circuit extends. A second electrically conducting overlayer is deposited substantially covering the array of unit cells and connected for current return. Each switching control circuit is connected to the second conducting overlayer. The second conducting overlayer also has vias through which each lead from the emitting elements extends to the switching circuit.

In certain embodiments, the Read-In Integrated switching control circuits of the array are CMOS.

In an exemplary configuration, the first and second conducting overlayers are copper.

Additionally in certain embodiments, one or both of the conducting overlayers is thermally conductive.

The features, functions, and advantages that have been discussed can be achieved independently in various embodiments of the present invention or may be combined in yet other embodiments further details of which can be seen with reference to the following description and drawings

### BRIEF DESCRIPTION OF THE DRAWINGS

FIG. 1 is a side section schematic of a generalized unit cell of an exemplary embodiment;

FIG. 2 is a partial top view of an exemplary embodiment RIIC showing a subset of the array of unit cells; and,

FIGS. 3A-3D are exemplary views of the RIIC of FIG. 2 with subsets of pixels in one row of unit cells illuminated.

### DETAILED DESCRIPTION

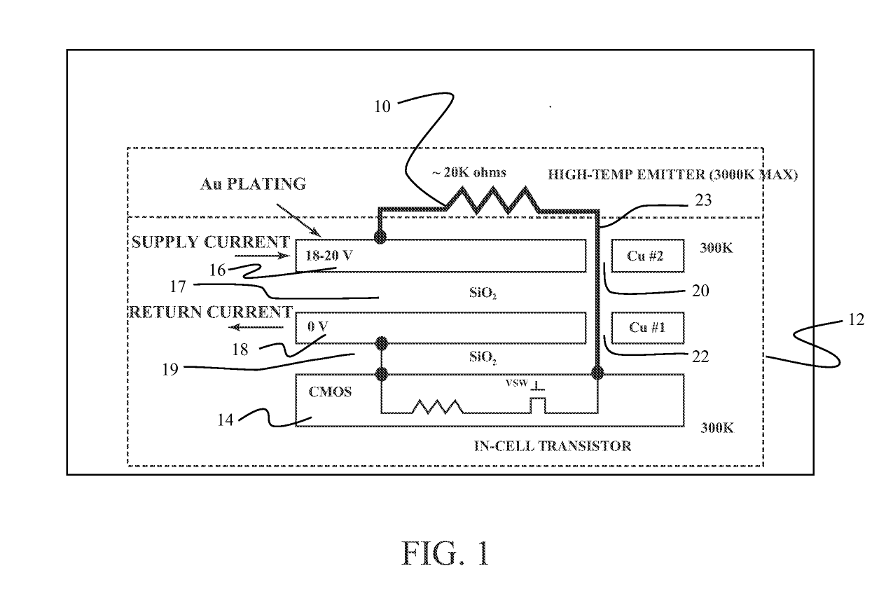

The embodiments described herein provide a high-current “Read-In Integrated Circuit” (RIIC) device that contains a large number of unit cell elements that will have the capability to be mated to “emitting” devices for use in infrared scene projection applications. As generally described in FIG. 1, a high-temperature resistive element 10 as an emitter is shown mated to an emitting unit cell 12. For the embodiment shown, an emitter of approximately 20K ohms in resistance provides 3000K maximum temperature capability. The unit cell incorporates a CMOS control circuit 14 providing switching control for the emitter. Other example emitter technologies such as infrared (IR) light emitting diode arrays, IR laser diode arrays, IR emitting photonic crystal arrays and liquid crystal on silicon IR emitting arrays may also be mated to the unit cell in alternative embodiments. The emitting unit cells are arranged in an array as in a standard RIIC device and copper plating overlayer 16 for supply current and overlayer 18 for return current extend over the array separated by dielectric layers 17 and 19 respectively with vias 20 and 22 for circuit isolation in each cell allowing lead 23 from the resistive element 10 to pass through the overlayers for connection to the CMOS control circuit 14. For the embodiment shown, the dielectric layers are silicon dioxide (SiO₂). The thickness of the copper overlayers is determined based upon the maximum amount of current required to operate the emitting devices at prescribed maximum radiance levels.

The copper overlayers on the wafers of the RIIC die remove the voltage drops produced within the emitting core of previous high-current scene projection devices. Additionally, the presence of the highly thermally conductive copper overlayers on the RIIC effectively limit lateral thermal migration, thus limiting the local heating spatially resulting in a predominance of infrared radiation as opposed to lateral thermal diffusion from adjacent cells. In addition, the high thermal conductivity of the copper overlayers create a condition in which the copper overlayers act as a thermal shield, isolating the underlying CMOS circuitry from high levels of thermal radiation and excessive heating.

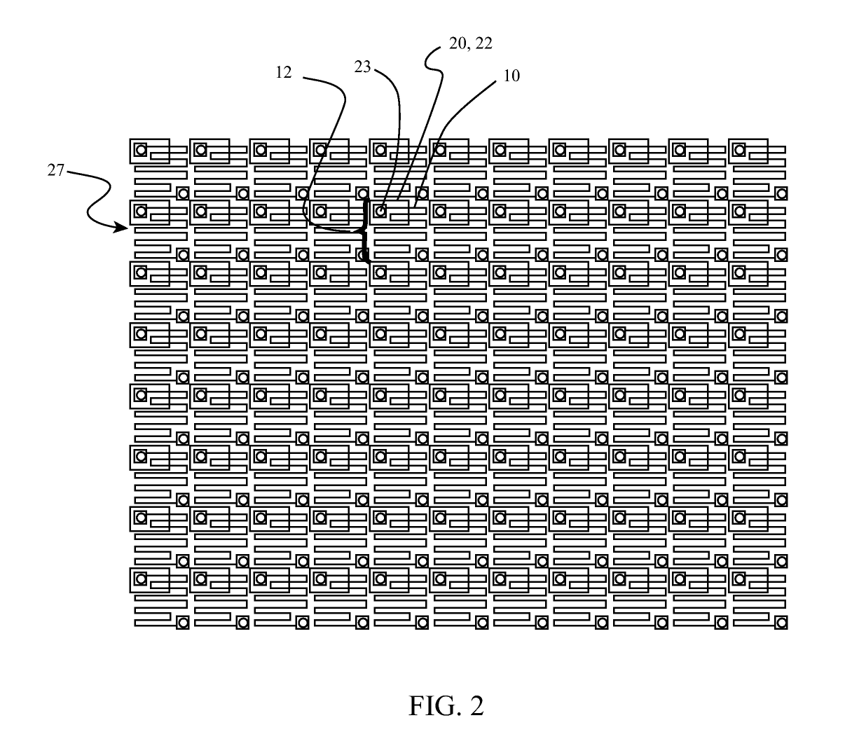

FIG. 2 shows in partial view an exemplary implementation for test of the embodiment disclosed in FIG. 1 wherein 7K ohm nichrome resistors 24 were photolithographically patterned in isolated layers on top of 256×256 RIIC devices (such as NOVA-012 RIIC devices produced by Nova Research, Solvang, Calif.) that have a 51 um emitting pixel pitch. Each unit cell 12 shows top copper overlayer 16 and the associated vias 20 and 22 in each cell. While not appropriate for high temperature emission applications, the embodiments disclosed herein could be well utilized for lower temperature (i.e., lower dynamic range than achievable when used with MWIR LED arrays, high temperature resistive emitters, photonic crystals, etc.) but high speed (up to approximately 800 Hz full frame in the analog input mode) applications at very low cost.

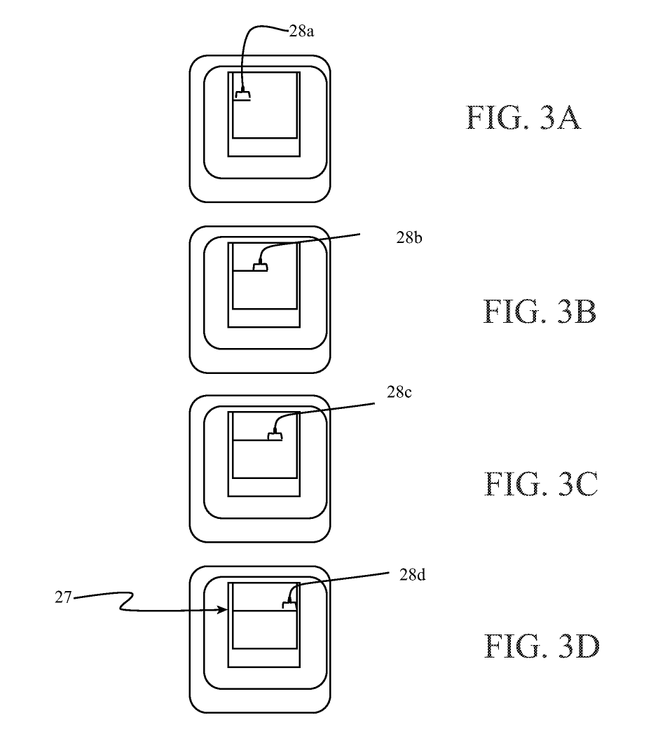

FIGS. 3A-3D show a demonstration of the operation of the exemplary test circuit 26 shown in partial view in FIG. 2. A simple stimulus pattern was implemented that energizes sets of 32 pixels in an individual row until the entire row 27 (as seen in FIG. 2) is “lit”. In FIG. 3A a first 32 pixel set 28a in the exemplary row is illuminated. In FIG. 3B a second adjacent 32 pixel set 28b is also illuminated. In FIG. 3C, the third adjacent 32 pixel set 28c is illuminated while in FIG. 3d the fourth adjacent 32 pixel set 28d is illuminated to complete the row. The pattern then continues to the next row and eventually addresses all pixels in the device from the top to the bottom of the device.

Having now described various embodiments of the invention in detail as required by the patent statutes, those skilled in the art will recognize modifications and substitutions to the specific embodiments disclosed herein. Such modifications are within the scope and intent of the present invention as defined in the following claims.

What is claimed is:

1. A Read-In Integrated Circuit scene generator comprising:
an array of unit cells, each cell having a switching control circuit;
an array of emitting elements, each emitting element associated with one unit cell and connected with a lead to the switching control circuit of the associated cell;
a first electrically conducting overlayer substantially covering the array of unit cells and connected for current supply, each emitting element connected to the first conducting overlayer, said first conducting overlayer having a first plurality of vias through which each first lead extends; and
a second electrically conducting overlayer substantially covering the array of unit cells and connected for current return, each switching control circuit connected to the second conducting overlayer, said second conducting overlayer having a second plurality of vias through which each first lead extends.

2. The Read-In Integrated Circuit scene generator of claim 1 wherein the switching control circuit is CMOS.

3. The Read-In Integrated Circuit scene generator of claim 1 wherein the first conducting overlayer is copper.

4. The Read-In Integrated Circuit scene generator of claim 1 wherein the second conducting overlayer is copper.

5. The Read-In Integrated Circuit scene generator of claim 1 wherein at least one of the first and second electrically conducting overlayers is thermally conductive.

6. A scene generator comprising:
a Read-In Integrated Circuit (RIIC) having an array of unit cells;
a first electrically conducting overlayer deposited covering the array of unit cells in the RIIC and connected for current supply;
a second electrically conducting overlayer deposited covering the array of unit cells in the RIIC and connected for current return;
an array of emitting elements corresponding to the array of unit cells deposited over the first electrically conducting overlayer and connected thereto, said first and second overlayers each having a plurality of vias, one of said plurality corresponding to each unit cell, each emitting element connected to the corresponding unit cell through said one of the plurality of vias and each of said unit cells connected to the second conducting overlayer.

7. The scene generator of claim 6 wherein the switching control circuit is CMOS.

8. The scene generator of claim 6 wherein the first conducting overlayer is copper.

9. The scene generator of claim 6 wherein the second conducting overlayer is copper.

10. The scene generator of claim 6 wherein at least one of the first and second electrically conducting overlayers is thermally conductive.

11. A method for scene generation comprising:
providing a RIIC having an array of unit cells, each cell having a switching control circuit;
depositing a first electrically conducting overlayer over the RIIC array with a plurality of vias;
depositing a second electrically conducting overlayer over the RIIC array with a plurality of vias;
connecting the first conducting overlayer for current supply;
connecting the second conducting overlayer for current return;
depositing an array of emitting elements over the first conducting layer, said emitting elements connected to the first conducting array and connected through the plurality of vias in the first and second conducting overlayer to the RIIC array; and,
connecting the RIIC array to the second conducting overlayer.

12. The method of claim 11 further comprising conducting heat generated by the emitting elements through at least one of the first and second conducting overlayers.
